(19) United States
(12) Patent Application Publication
(10) Pub. No.: US 2022/0400574 A1
(43) Pub. Date: Dec. 15, 2022

(54) MODULAR DATA CENTRE

(71) Applicant: DATAQUBE GLOBAL LTD, Okehampton (GB)

(72) Inventor: David James KEEGAN, Cambridge (GB)

(21) Appl. No.: 17/839,872

(22) Filed: Jun. 14, 2022

(30) Foreign Application Priority Data
Jun. 14, 2021 (GB) 2108484.3

(51) Int. Cl. H05K 7/18; H05K 7/20

(52) U.S. Cl. CPC H05K 7/18; H05K 7/20572; H05K 7/20145

(57) ABSTRACT

A modular data centre unit is provided comprising: at least one module, each module defining an interior space, intended to house computing equipment mounted on racks or cabinets; and at least one cooling module configured to cool the inner space of the at least one module, wherein the at least one module is configured to enable horizontal and/or vertical arrangement in which a plurality of modules are arranged adjacent to one another.

### CROSS REFERENCE TO RELATED APPLICATIONS

This application claims benefit of priority pursuant to 35 U.S.C. § 119(a) of United Kingdom patent application no. GB2108484.3 filed 14 Jun. 2021, which is hereby incorporated herein by reference in its entirety.

### FIELD OF THE INVENTION

The present application relates generally to a modular data centre and in particular a modular data centre that is compact and scalable.

### BACKGROUND OF THE INVENTION

Data centres are typically made up of large rooms or buildings, inside of which a great number of pieces of electronic equipment are concentrated, for the purpose of processing data, for example, for a company or organisation. Typically, they are housed in containers or dedicated data centre rooms and include space for personnel to enter and access the data centre.

Data centres usually take up a lot of space as they house hundreds of racks containing computing equipment and various storage modules, power modules, and network modules. It can be time exhaustive and costly to scale up a data centre that has already been deployed.

The modular data centre described is flexible and easy to reconfigure, improves scaling up and down, minimises power consumption and the space required to deploy such a data centre, improves security, improves cooling environments, and maintains the stability of and protects computing equipment when the modular data centre unit is deployed in earthquake zones.

### SUMMARY

A modular data centre unit is provided comprising at least one module, each module defining an interior space, intended to house computing equipment mounted on racks or cabinets, and at least one cooling module configured to cool the inner space of the at least one module, wherein the at least one module is configured to enable horizontal and/or vertical arrangement in which a plurality of modules are arranged adjacent to one another.

### BRIEF DESCRIPTION OF THE DRAWINGS

The modular data centre unit will now be described, by way of example only, with reference to the accompanying drawings, in which:

FIG. 1 illustrates a frame structure of a modular data centre unit capable of supporting five modules;

FIG. 2A illustrates a frame structure of a modular data centre unit supporting one module within the frame structure, with all external panels and plates attached;

FIG. 2B illustrates another embodiment of a frame structure of a modular data centre unit supporting one module within the frame structure, with all external panels and plates attached;

FIG. 3A illustrates a frame structure of a modular data centre unit supporting five modules within the frame structure;

FIG. 3B illustrates another embodiment of a frame structure of a modular data centre unit supporting five modules within the frame structure;

FIG. 4 illustrates a module of a modular data centre unit;

FIG. 5 illustrates a frame structure of a modular data centre unit supporting three modules within the frame structure with all external panels and plates attached, the modules housing racks and attached via side faces of the modules;

FIG. 6A illustrates a frame structure of a modular data centre unit supporting three modules within the frame structure with all external panels and plates attached, the modules attached via side faces and comprising three cooling modules;

FIG. 6B-D illustrates three sections of the frame structure shown in the modular data centre unit of FIG. 6A in an exploded view, including a space to house the three cooling modules;

FIG. 7A illustrates a frame structure of a modular data centre unit supporting a plurality of modules within the frame structure with all external panels attached, the modules attached via side faces and comprising a plurality of cooling modules;

FIG. 7B illustrates the right-hand most section of the frame structure of the modular data centre unit of FIG. 7A, including a space to house one cooling module only;

FIG. 8 illustrates a frame structure of a modular data centre unit supporting a plurality of data modules within the frame structure, the plurality of data modules connected via any of the side faces, top faces and bottom faces;

FIG. 9A illustrates an embodiment of a modular data centre unit comprising a frame structure supporting a plurality of data centres within the frame structure and a sealed air plenum;

FIG. 9B illustrates a plan view of the embodiment of a modular data centre unit of FIG. 9A, further comprising adiabatic cooling; and

FIG. 10 illustrates a plan view of an embodiment of a modular data centre unit comprising a frame structure supporting a plurality of data centres within the frame structure and a plurality of cooling modules.

### DETAILED DESCRIPTION OF THE INVENTION

The following detailed description is not intended to limit the described embodiments of the application and uses of the described embodiments.

A modular data centre unit 100 comprises at least one module 300, each module 300 defining an interior space, intended to house computing equipment mounted on racks or cabinets 500, and at least one cooling module 600 configured to cool the inner space of the at least one module 300. The modular data centre unit 100 is configured to enable horizontal and/or vertical arrangement in which a plurality of modules are arranged adjacent with one another. The modular data centre unit 100 may comprise a frame structure 110 which is a structural frame configured to house the module(s).

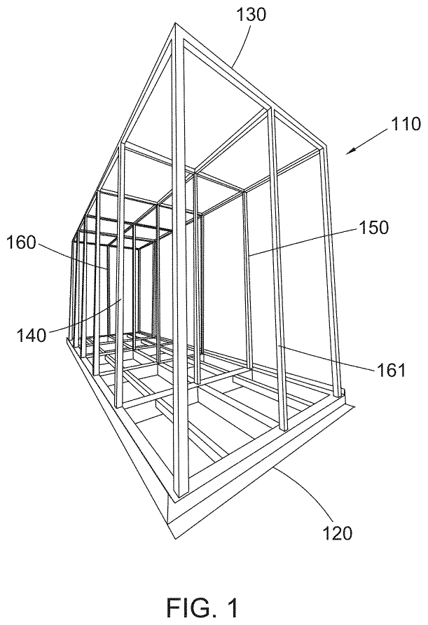

FIG. 1 illustrates an example of a frame structure 110 of a modular data centre unit 100. A similar frame structure may be used in any embodiment. The frame structure comprises a bottom face 120, a top face 130, a front face 140, a back face 150, and two side faces 160, 161. The frame structure 110 may be of any required size. The particular frame structure 110 illustrated in FIG. 1 has five “bays” each capable of supporting a module 300, but the frame structure 110 may be sized to fit a single module, or any number of modules as desired. The frame structure 110 may be increased or decreased as required to expand or contract the size of the modular data centre unit 100, for instance, to provide additional computing equipment or to remove computing equipment.

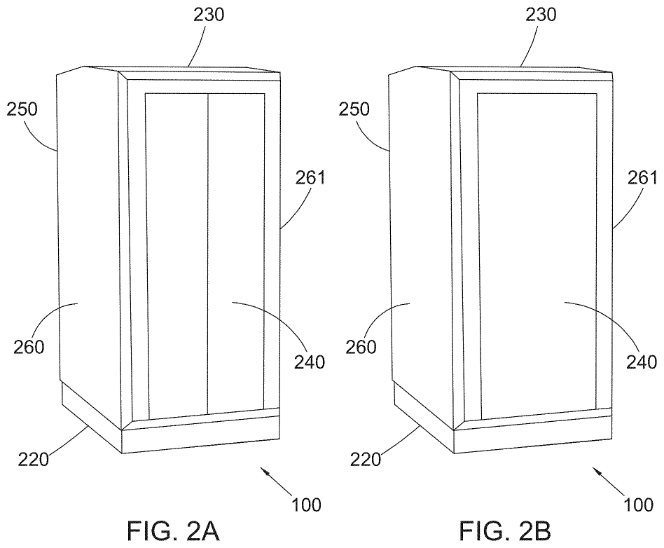

FIG. 2A illustrates a frame structure 110 of a modular data centre unit 100 configured to support one module, with all external panels of the frame structure 110 attached. A bottom face 120 of the modular data centre unit 100 may comprise a base plate 220 attached to the frame structure, wherein the frame structure is upright and the base plate 220 lies in the horizontal plane. A top face 130 of the modular data centre unit 100 may comprise a top plate 230 attached to the frame structure. A front face 140 of the modular data centre unit 100 may comprise a front panel 240 attached to the module 300. In the embodiment illustrated in FIG. 2A, the front panel 240 is a pair of doors. A back face 150 of the modular data centre unit 100 may comprise a back panel 250 attached to the module 300. Two side faces 160, 161 of the modular data centre unit 100 may comprise two outer side panels 260, 261 attached to the frame structure. Alternatively, the front panel 240 and back panel 250 are attached to the frame structure 110. The front panel 240 may be referred to as an outer front door 240 and the back panel 250 may be referred to as an outer back door 250.

FIG. 2B illustrates a frame structure 110 of a modular data centre unit 100 configured to support one module 300, with all external panels of the frame structure attached. In the embodiment illustrated in FIG. 2B, the front panel 240 of the module 300 is a single door, hinged onto a vertical support of the module 300. Alternatively, the front panel 240 is attached to the frame structure 110.

Any of the front panel 240 and back panel 250 connected to the module 300 may be detached.

In some embodiments, any of the base plate 220, top plate 230, and outer side panels 260, 261 may be each configured to be detached from the frame structure 110 so at least two modules 300 can be connected in any configuration via the frame structure 110, including in both horizontal and vertical planes.

The material of the base plate 220, top plate 230, front panel 240, back panel 250, and outer side panels 260, 261 may be any material suitable for fulfilling the purpose of a panel and may for instance be any of the following: steel, and/or precast concrete, and/or, re-enforced insulation, and/or wire, and/or timber boarding, and/or timber boarding within a steel enclosure.

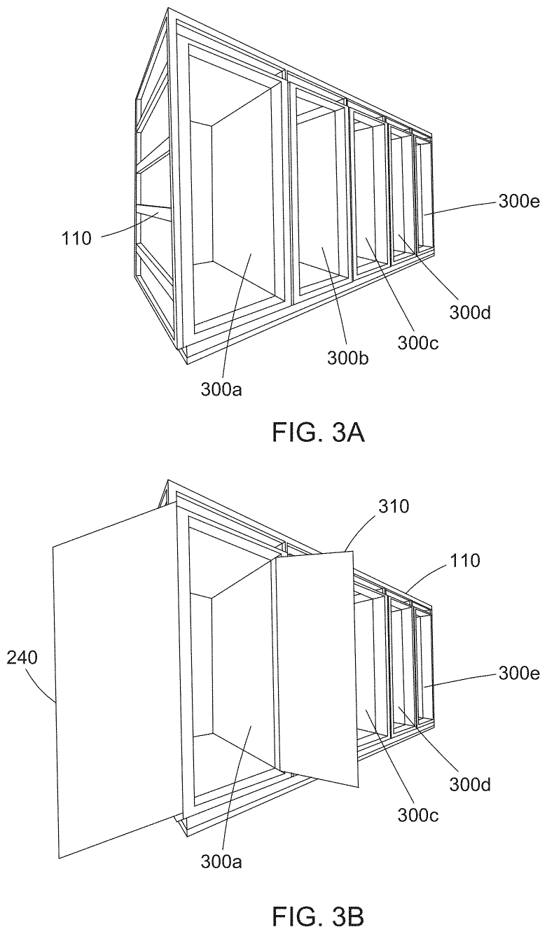

FIG. 3A illustrates a frame structure 110 of a modular data centre unit 100 supporting five modules 300a, 300b, 300c, 300d, 300e. The modules 300a, 300b, 300c, 300d, 300e and any module 300 in any embodiment each define an interior space and are configured to support racks 500 upon which computing equipment is mounted. The computing equipment may comprise, for example, data modules, power modules, and network modules. The computing equipment may further comprise, for instance, at least one of the following: a server, an active switchboard, a passive switchboard, an uninterruptible power supply (UPS), and power infrastructure. The modules 300a, 300b, 300c, 300d, 300e may be electrically connected to each adjacent module 300a, 300b, 300c, 300d, 300e. The connection means may be holes and/or electrical trunking to allow the connection of wiring of the computing equipment mounted on racks 500. Electrical trunking systems are used to carry a compound current where various electrical cables come together. Electrical trunking may be used to protect cables and provide space for other electrical equipment. The frame structure 110 supporting each module is connected via a connection means, such as, concealed fixing with an insulated partition. The frame structure 110 may be structurally separated from each module 300a, 300b, 300c, 300d, 300e and the frame structure 110 may further be electrically isolated from the racks 500 within each module 300a, 300b, 300c, 300d, 300e. Each module 300 comprises at least one rack 500. An unlimited number of modules 300 may be connected in a modular arrangement, which results in a fully scalable solution that can be implemented anywhere, in custom configurations.

FIG. 3B illustrates a frame structure 110 of a modular data centre unit 100 supporting five modules 300a, 300b, 300c, 300d, 300e, wherein module 300a is shown with two doors comprising panels 310, 240 to illustrate door options. The front panel 240 is attached to the module 300 and forms an outer door of the module 300 and the door 310 of the module 300 forms an inner door of the module 300. Alternatively, the front panel 240 may be attached to the frame structure 110 and the other door 310 is a door of the module 300a. The front panel 240 forms an outer door of the modular data centre unit 100 and the door 310 of the module forms an inner door of the modular data centre unit 100. An optional internal glass door may also be provided. The internal glass door may provide a hermetic seal to the module. Similar door arrangements may be provided for each bay of the frame structure 110 or a subset of the bays of the frame structure. This double door arrangement improves the security of the modular data centre unit 100, as well as the insulation and access.

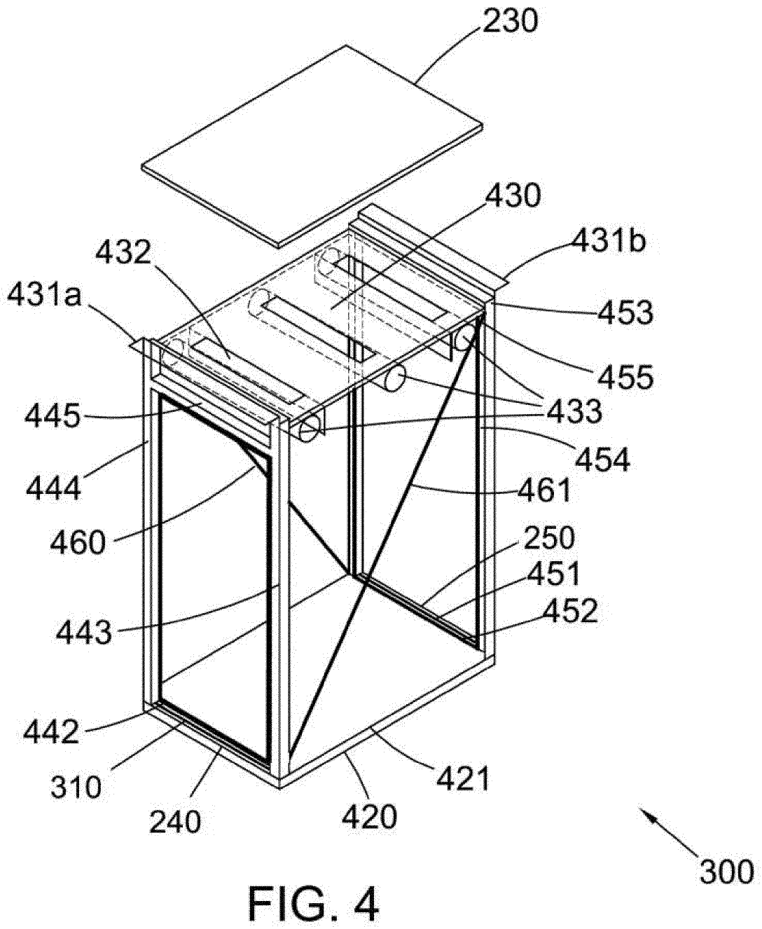

FIG. 4 illustrates a modular data centre unit 100 comprising a frame structure 110 and one module 300 defining an interior space, intended to house computing equipment mounted on racks or cabinets 500 (not shown). This results in a modular data centre unit with a single module as shown for instance in FIG. 2A.

The bottom face of the module 300 comprises a frame plate 421, with an internal floor 420 optionally disposed under the frame plate 421. The top face of the module 300 comprises a ceiling 430, and optionally comprises a rain shield internal wall 432 and/or a rain cover 431. The top plate 230, which may be attached to the rain cover 431 and/or the ceiling 430, is configured to be the top of the outer side of the top face 130 attached to the frame structure 110. The top face of the module 300 may further comprise an air channel 433. The air channel 433 is illustrated as an outlet and/or inlet of the module 300. The top face 130 may further comprise an air gap cover which may be attached to the ceiling 430.

The embodiment of FIG. 4 illustrates a modular data centre unit 100 with the top plate 230 visibly detached to understand the connection of the module 300 with the frame structure 110. The base plate 220 and top plate 230 may be attached to the frame structure 110 and may be optionally connected with the module 300 if the module 300 is inside the frame structure 110.

The front face of the module 300 may be optionally attached to a front glass door 442, wherein the user can see at least one rack within the module 300. A front internal panel 445 may be attached to the front glass door 442. An inner front door 310 may be attached to the front internal panel 445. An outer front door 240 may be attached to a front door frame 444 and/or optionally a front upright door frame 443 via maglocks, hinges, and lockbolts. The front door frame 444 and/or optionally the front upright door frame 443 may be optionally attached to the front glass door 442 and/or optionally attached to the inner front door 310. Alternatively the outer front door 240 may be attached to the front face 140 of the frame structure 110.

The back face of the module 300 may be optionally attached to a back glass door 452, wherein the user can see at least one rack within the module 300. A back internal panel 455 may be attached to the back glass door 452. An inner back door 451 may be attached to a back internal panel 455. An outer back door 250 may be attached to a back door frame 454 and/or optionally a back upright door frame 453 via maglocks, hinges, and lockbolts. The back door frame 454 and/or optionally the back upright door frame 453 may be optionally attached to the back glass door 452 and/or optionally attached to the inner back door 451. Alternatively the outer back door 250 may be attached to the back face 150 of the frame structure 110.

The side faces of the module 300 may comprise inner side panels 460, 461 and may additionally comprise an upright frame attached to the inner side panels 460, 461. Outer side panels 260, 261 may be attached to each of the side faces 160, 161 of the modular data centre unit 100.

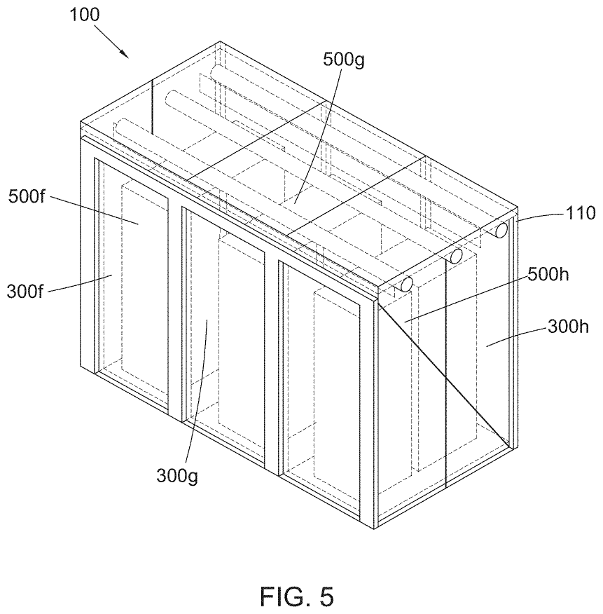

FIG. 5 illustrates a frame structure 110 of a modular data centre unit 100 with three modules 300f, 300g, 300h within the frame structure 110, attached via side faces. The embodiment illustrates a plurality of modules 300f, 300g, 300h arranged adjacent to, for instance contiguously with, one another, each housing computing equipment mounted on racks 500f, 500g, 500h. The part of the frame structure 110 housing the outer modules 300f, 300h comprises outer side panels 260, 261 attached to the frame structure 110 and the modules 300f, 300h each comprise upright frames attached to inner side panels 460, 461 of each module 300f, 300h. The outer side panels 260, 261 of the frame structure 110 supporting the inner module 300g are detached from the frame structure 110 and the inner side panels 460, 461 of the module 300g are attached to the uprights of the frame structure 110. Although not clear from the line drawing, the frame structure 110 has all base plates 220 and top plates 230 attached, and the modules 300f, 300g, 300h have all front panels 240 and back panels 250 attached.

The top of the frame structure 110 comprises a top face 130. The top face 130 of each module 300f, 300g, 300h may comprise a ceiling 430, a rain cover 431, rain shield internal wall 432 and/or an air channel 433, as described in FIG. 4. The bottom face, top face, front face, back face and side faces of each of the modules 300f, 300g, 300h may each comprise the features as outlined for the module 300 of FIG. 4.

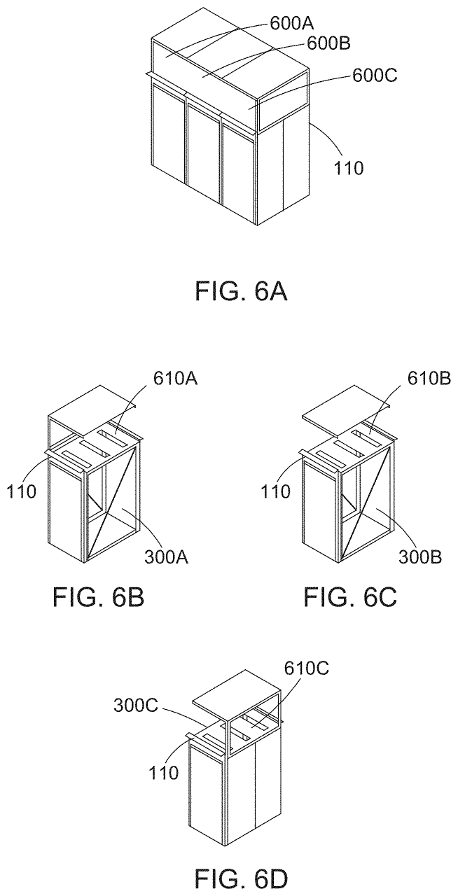

FIGS. 6A-D illustrate a modular data centre unit 100 comprising a frame structure 110 and modules 300 as described above. Each of FIGS. 6A-D illustrate the modular data centre unit 100 comprising at least one cooling module 600 configured to cool the inner space 610 of a module, wherein each cooling module 600 is laterally delimited to the top face 130 of the modular data centre unit 100. The cooling module may be laterally delimited to any face 120, 130, 140, 150, 160, 161 of each of the modules.

FIG. 6A illustrates an embodiment with a plurality of modules 300A, 300B, 300C arranged adjacent to one another, each housing computing equipment mounted on racks, with the frame structure 110 supporting the modules 300A, 300B, 300C. The part of the frame structure 110 supporting the outer modules 300A, 300C comprises outer side panels attached to the frame structure 110 and the modules 300A, 300C comprise upright frames attached to the inner side panels of the modules 300A, 300C. The outer side panels of the frame structure 110 supporting the inner module 300B are detached from the frame structure 110 and the inner side panels of the module 300B are attached to the uprights of the frame structure 110. Cooling modules 600A, 600B, 600C are laterally delimited to the top face 130 of the modular data centre unit 100.

FIGS. 6B-D illustrate three sections of the frame shown in the modular data centre unit 100 of FIG. 6A in an exploded view, including a space 610A, 610B, 6100 to house the three cooling modules. The plurality of modules 300A, 300B, 300C being housed in the frame structure 110 have space to house cooling modules 610A, 610B, 6100.

In some embodiments the modular data centre unit 100 comprises at least one cooling module 600 configured to cool the inner space of a module 300, each cooling module 600 being laterally delimited by at least one face 120, 130, 140, 150, 160, 161 of the modular data centre unit 100. The cooling module 600 may be configured to be remote or to be connected to any part of the module 300 and/or frame structure 110. A part of module 300 and/or frame structure 110 may be the bottom face 120, top face 130, front face 140, back face 150, or side faces 160, 161. In some embodiments, the cooling module 600 may be connected to the top face of the module 300 via the frame structure 110 and beneath the top plate 230. In further embodiments, the cooling module 600 may be attached to the side of the module 300 via the frame structure 110. Each cooling module 600A, 600B, 600C comprises a cooling system incorporating, for instance, immersive technology, monoblock cooling, modular cooling, adiabatic cooling, chilled water, or refrigerant gas. In some embodiments, a different cooling system is used for each module 300. In some embodiments, a different cooling system is used for at least one module 300A. In some embodiments, a different cooling system is used for at least two modules 300A, 300B.

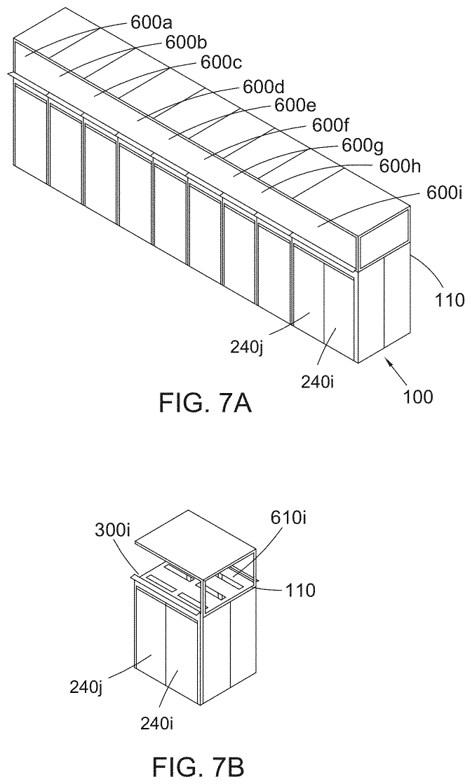

FIGS. 7A-B illustrate a modular data centre unit 100 comprising modules 300 as described above.

FIG. 7A illustrates the frame structure 110 of a modular data centre unit 100 housing a plurality of modules attached to a plurality of cooling modules 600a, 600b, 600c, 600d, 600e, 600f, 600g, 600h, 600i. The cooling module 600i on the right-hand most section of the modular data centre unit 100 is configured to cool at least one module 300i, with front panels configured to be two doors 240i, 240j.

FIG. 7B illustrates the right-hand most section of the frame structure 110 of the modular data centre unit 100 shown in FIG. 7A, wherein the at least one module 300i has space to house the cooling module 600i. The front face and back face of the at least one module 300i comprise two front panels 240i, 240j and two back panels configured to be front doors 240i, 240j and back doors attached to the at least one module 300i.

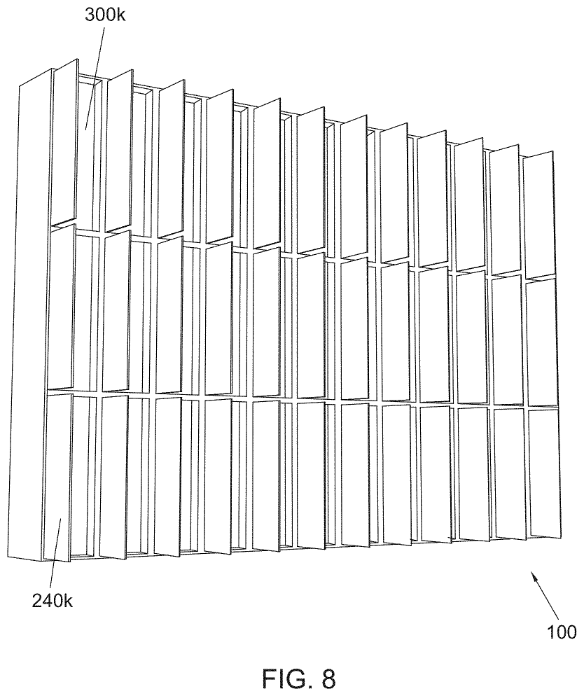

FIG. 8 illustrates a modular data centre unit 100 comprising a frame structure 110 and a plurality of modules 300k that are arranged adjacent to one another, within the frame structure 110. The plurality of modules 300k are connected via any of the top faces, bottom faces and side faces. To form connections with adjacent modules, top plates, bottom plates and outer side panels of the frame structure 110 are detached. Each front panel 240k of the plurality of modules 300k is configured to be a front outer door 240k. Each back panel 250 of the plurality of modules 300k may be configured to be a back outer door 250.

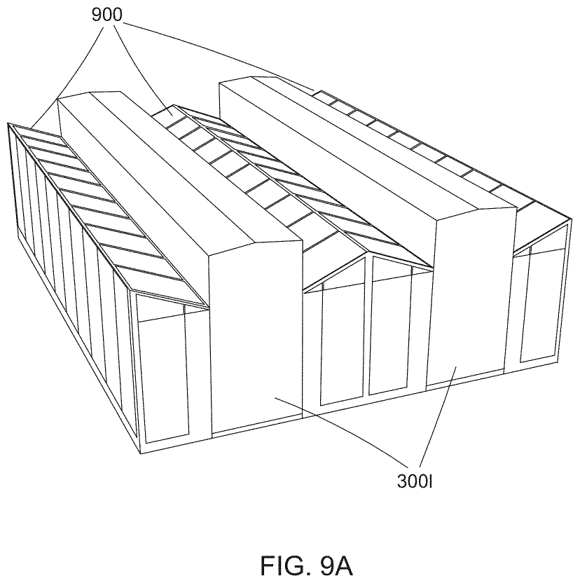

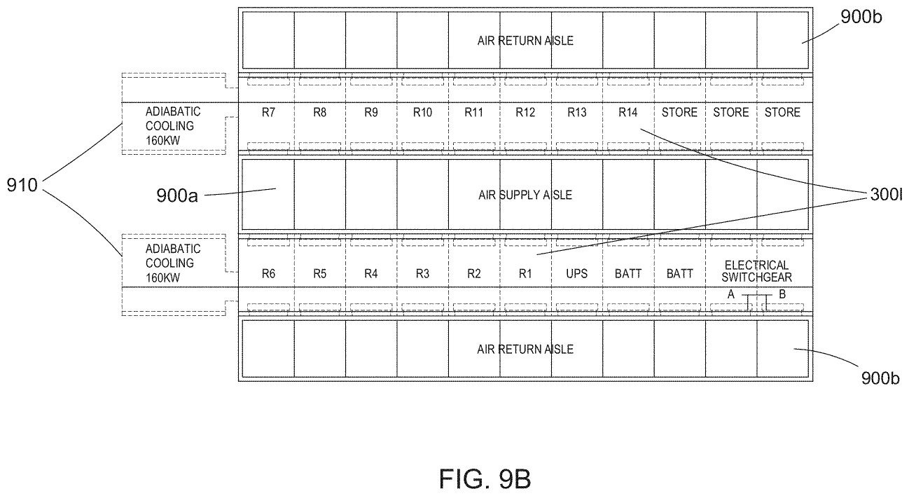

FIG. 9A illustrates an embodiment if a modular data centre unit 100 comprising frame structure 110 and a plurality of modules 300l, wherein the plurality of modules 300l are arranged adjacent to one another within the frame structure. The plurality of modules 300l may be arranged in any configuration. In this embodiment, the cooling module comprising a sealed air plenum 900 is configured to surround the plurality of modules 300l.

The sealed air plenum 900 may be attached to each of the plurality of modules 300l wherein air can be distributed throughout the plurality of modules 300l in the frame structure 110 and around the rack(s) and computing equipment in the plurality of modules 300l. Horizontal and vertical sections may be installed into the plenum to give further control of the air distribution. The plenum space can facilitate air circulation for air conditioning systems, by providing pathways for either conditioned or return airflows, usually at greater than atmospheric pressure. The plenum may also act as a rainwater or adverse weather canopy.

FIG. 9B illustrates a plan view of an embodiment of a modular data centre unit comprising a frame structure 110 housing a plurality of modules 300l with a cooling system comprising a sealed air plenum 900 and adiabatic cooling 910. Adiabatic cooling is the process of reducing heat through a change in air pressure caused by volume expansion. Adiabatic processes have enabled free cooling methods, which are economical methods of using low external air temperatures to assist in chilling water, which can then be used in air conditioning systems. The chilled water can either be used immediately or stored.

The sealed air plenum 900 is illustrated with air supply aisles 900a and air return aisles 900b, and adiabatic cooling 910 is also provided. The plurality of modules 300l house computing equipment. This computing equipment is mounted on racks and is labelled in FIG. 9A as racks R1, R2, R3, . . . , R14, storage modules STORE, power modules or more specifically uninterruptible power supplies UPS, batteries BATT, and electrical switchgear ELECTRICAL SWITCHGEAR A, ELECTRICAL SWITCHGEAR B.

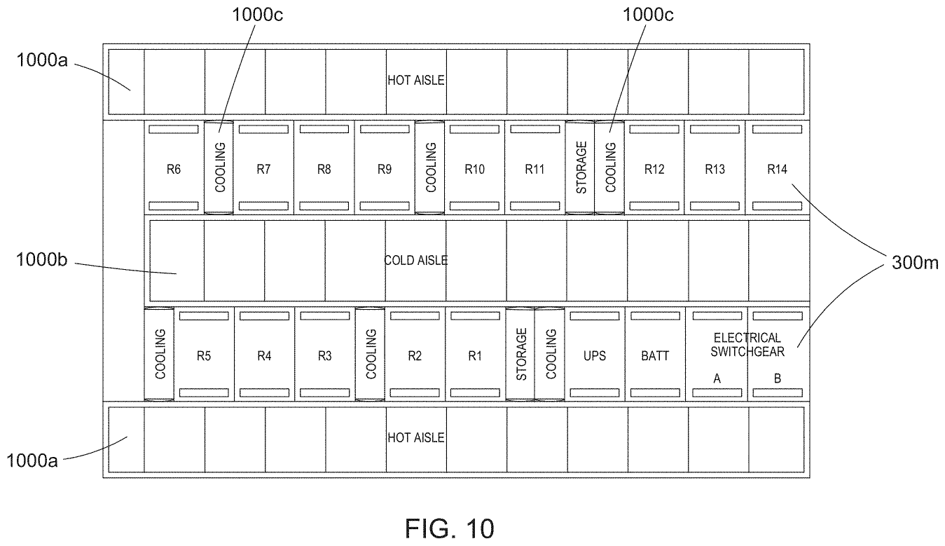

FIG. 10 illustrates a plan view of an embodiment of a modular data centre unit 100 comprising a frame structure 110 housing a plurality of modules 300m and a plurality of cooling modules 1000.

The cooling system comprising a plurality of cooling modules 1000 is labelled in FIG. 10 as HOT AISLE 1000a, COLD AISLE 1000b, and COOLING 1000c. The plurality of modules 300m house computing equipment. This computing equipment is mounted on racks and is labelled in FIG. 10A as racks R1, R2, R3, . . . , R14, storage modules STORE, power modules or more specifically uninterruptible power supplies UPS, batteries BATT, and electrical switchgear ELECTRICAL SWITCHGEAR A, ELECTRICAL SWITCHGEAR B.

The choice of having a different cooling system for each module or for a given module provides flexibility and, in some cases, provides a more cost-effective solution.

Immersive technology may include immersive cooling. Immersive cooling may also be referred to as submersion cooling or immersion cooling. Immersive cooling is a method of cooling wherein the computing equipment within a rack is submerged in a thermally conductive liquid or coolant. Heat is removed from the system by circulating liquid into direct contact with hot components, then through cool heat exchangers. Fluids suitable for immersion cooling have very good insulating properties to ensure that they can safely come into contact with energized electronic components.

Generally, most air conditioning units comprise a heat exchanger that use the flow of refrigerant from one set of coils, where heat is collected, to another set of coils, where heat is dispersed. Monoblock units have both sets of coils inside a single housing. Monoblock units would be attached to the racks that are to be cooled, with there being air pipes attached that direct heated air outside.

When using refrigerant gas, the refrigerant flows into a compressor where it is compressed and pressurised as a hot gas. The refrigerant is then pushed to the condenser which turns the vapour into liquid and absorbs some of the heat. The refrigerant then proceeds to the expansion valve where it expands, losing pressure and heat. The refrigerant coming out of the expansion valve is cold and slow due to the loss of pressure. It enters the evaporator in a liquid state where the exchange of heat takes place thus cooling the load inside the refrigerator. As the gas cools down the load, it absorbs the heat which turns it into a gas. The gas is then pushed back into the compressor where it can start the cycle again.

Although having a cooling system such as adiabatic cooling, or direct expansion cooling with chilled water would provide a space for a human to walk through, smaller modular data centre unit 100s may be provided without the need to provide allocated space for a human to walk through within the data centre unit. Each module is fully occupied with computing equipment and does not have allocated space for a human. Many other data centre units have larger modules with allocated space for humans, meaning more space is required to deploy the unit and more energy is required to cool the modules. The described embodiment results in less power consumption in building the modular data centre unit 100 as it requires less space to build and less building materials, and less power consumption needed for cooling the modular data centre unit 100. This also reduces the cost of implementation and increases the scalability. The power consumption and cost of cooling may be further reduced by internally lining each module with insulation to keep them cool for longer, meaning less power is needed for the cooling system.

In all embodiments the at least one module 300 defines an interior space. Computing equipment is housed within this space and is mounted on racks 500. The computing equipment may comprise, for example, storage modules, power modules, and network modules. The computing equipment may further comprise, for instance, at least one of the following: a server, an active switchboard, a passive switchboard, an uninterruptible power supply (UPS), and power infrastructure.

The modules 300 may include tracks along which the computing equipment may slide to insert the computer equipment into the module. The computing equipment may be provided in racks or cabinets 500.

Modules 300 have space to house racks 500 comprising computing equipment, this space provides flexibility in choosing racks 500 for use in the modular data centre unit 100. Each module 300 can be deployed separately by expanding the frame structure 110 as necessary to add extra bays and inserting another module 300 into the modular data centre unit 100, to provide housing for at least one rack 500 comprising computing equipment, or at least one cooling module 600 comprising a cooling system. The flexibility of the system is optimized by having modules 300 and an expandable frame structure 110, which may be expanded in any direction. In some embodiments, the configuration of the modules 300 and frame structure 110 in a modular data centre unit 100 can be chosen to fit any space, due to the removeable panels 220, 230, 240, 250, 260, 261 on any face 120, 130, 140, 150, 160, 161 of the frame structure 110 and/or the module 300. There is minimised space within each module 300.

In some embodiments, internal glass panels may be provided on the modules to increase the visibility of the computing equipment within the racks supported in the modules when the data centre doors are open and/or the outer panels are detached. This increases the security of the modular data centre unit. External doors, maglocks, and lockbolts further increase security. A security system may be provided within the modular data centre unit for even further increased security. As each module is deployed separately, expanding the frame structure to support each module, security is further increased because if someone were to open an external panel of the frame structure and/or external door of the module and/or internal door of the module and/or glass door of the module within the modular data centre unit, they would only have access to one module within the unit. Each module is structurally separated from adjacent modules within the structure by inner side panels and/or insulation.

The frame structure and/or each module of the modular data centre unit is made using a structurally sound material. The structurally sound material may be steel, or stainless steel, or mild steel, or box steel sections. To minimise the impact on the environment, the structurally sound material may additionally be timber, or plastic, or carbon fiber, or polycarbonate. Making the modular data centre unit out of timber could further minimise the impact on the environment caused through the production of materials.

The modular data centre unit may include a frame structure to receive a plurality of modules and cooling modules. Each module comprising a rack may be supported separately within the frame structure, with the module being separate from the frame structure.

In an embodiment, the frame structure may be configured to be resistant to movement, for example the frame structure may comprise seismic stabilizers. The frame structure may have a dual structure frame, wherein the frame structure can provide structural control through energy dissipation within the frame to enable stability when deployed in an earthquake zone. Dual structure frames are designed to dissipate energy within the frame structure. A dual structure frame provides support for gravity loads, and resistance to lateral loads. A dual structure frame may also be referred to as a dual triangulated frame. The frame structure may be configured to be a dual structure frame with isolation seismic stabilizers, the frame structure may be constructed from springs, concrete and/or rubber, allowing independent movement of the frame structure. In the triangulated form, the structural frames can move both vertically and horizontally at any given time to reduce the seismic impact within each of the modules. The frame structure may optionally comprise variable vibration mounts, which prevent excessive vibration within a structure by absorbing and dampening vibrations. As the frame structure is separate from the modules, the stability and protection of computing equipment within the modules is improved. This is especially useful when the modular data centre units are deployed in earthquake zones as the frame structure dissipates energy to prevent the movement of the computing equipment.

The modular data centre unit may further comprise a fire system, and/or a security system, and/or maglocks, and/or leak detection, and/or internally lined rockwool, and/or building management system, and/or DCIM, and/or infrastructure, and/or CCTV, and/or fire suppression, and/or wireways, and/or electrical switchgear.

In some embodiments, the modular data centre is configured to be deployed as a plurality of separate modules, with the frame structure unbuilt. For the ease and speed of implementation, these separate components are configured to be assembled onsite. This increases the scalability and flexibility of the modular data centre unit.

In some embodiments, the modular data centre unit may be configured to be unassembled and assembled onsite. In this embodiment, each of the at least one module and the frame structure are unassembled. Each of the at least one module and the frame structure may be considered as components of the modular data centre unit, therefore each of the separate components may be unassembled. The modular data centre unit may be containerised, and/or configured to be self-assembled, and/or configured to be deployed as a set of parts. In this embodiment, containerised means that the at least one module and/or frame structure and/or modular data centre unit can be packed into or transported by a container. The at least one module may be unassembled such that the at least one module is containerised. The at least one module may be unassembled such that the at least one module is configured to be deployed as a set of parts. The at least one module may be unassembled such that the at least one module can be self-assembled. The frame structure may be unassembled such that frame structure is containerised. The frame structure may be unassembled such that the frame structure is configured to be deployed as a set of parts. The frame structure may be unassembled such that the frame structure can be self-assembled. Each of these embodiments, alone or in combination, increases the efficiency of shipping and handling, and also means that the modular data centre can be more widely delivered and assembled. The modular data centre may be prefabricated and configured to be deployed as a set of parts and assembled onsite.

The modular data centre unit as described can meet the rising demand for new data centres or for expanding those already in place. They aim to make the same easier to build, speeding up their implementation and optimising the available space as much as possible.

Further embodiments are described in the following numbered clauses:

1. A modular data centre unit comprising:
at least one module, each module defining an interior space, intended to house computing equipment mounted on racks or cabinets; and
at least one cooling module configured to cool the inner space of the at least one module, wherein the at least one module is configured to enable horizontal and/or vertical arrangement in which a plurality of modules are arranged adjacent to one another.

2. The modular data centre unit according to clause 1, wherein the at least one module is configured to enable horizontal and/or vertical arrangement in which a plurality of modules are arranged contiguous with one another.

3. The modular data centre unit according to clause 1 or clause 2, further comprising a frame structure configured to support at least the at least one module, wherein the frame structure comprises a front face, a back face, two side faces, a bottom face, and a top face.

4. The modular data centre unit according to clause 3, wherein the frame structure is a dual structure frame with variable vibration mounts.

5. The modular data centre unit according to clause 3 or clause 4, wherein the frame structure comprises seismic stabilizers.

6. The modular data centre unit according to any of clauses 3 to 5, wherein the frame structure is a structurally sound material, such as, steel, or stainless steel, or mild steel, or box steel sections, or timber, or plastic, or carbon fiber, or polycarbonate.

7. The modular data centre unit according to any preceding clause, wherein the module is a structurally sound material, such as, steel, or stainless steel, or mild steel, or box steel sections, or timber, or plastic, or carbon fiber, or polycarbonate.

8. The modular data centre unit according to any preceding clause, wherein the at least one module comprises connection means to connect the computing equipment.

9. The modular data centre unit according to any of clauses 3 to 8, wherein the frame structure comprises connection means to connect adjacent frame structure and modules.

10. The modular data centre unit according to clause 8 or clause 9, wherein the connection means to connect modules or to connect the computing equipment are holes and electrical trunking to allow the connection of wiring.

11. The modular data centre unit according to clause 9, wherein the connection means to connect the adjacent frame structure is concealed fixing with an insulated partition.

12. The modular data centre unit according to any of clauses 3 to 11, wherein the frame structure is structurally separate from each module, and each module is structurally separate from adjacent modules.

13. The modular data centre unit according to any of clauses 3 to 12, wherein the frame structure is electrically isolated from the racks within each module.

14. The modular data centre unit according to any of clauses 3 to 13, wherein the frame structure is configured to allow the connection of racks within modules in horizontal and vertical planes.

15. The modular data centre unit according to any preceding clause, wherein the computing equipment is at least one of:
a storage module;
a power module; and
a network module.

16. The modular data centre unit according to any preceding clause, wherein the computing equipment is at least one of:
a server;
an active switchboard;
a passive switchboard;
an uninterruptible power supply (UPS); and
power infrastructure.

17. The modular data centre unit according to any preceding clause, wherein the at least one cooling module comprises a cooling system configured to be remote or to be connected to any part of the at least one module of the modular data centre unit.

18. The modular data centre unit according to any preceding clause, wherein the cooling module comprises a cooling system incorporating: immersive technology, monoblock cooling, modular cooling, adiabatic cooling, chilled water, or refrigerant gas.

19. The modular data centre unit according to any preceding clause, further comprising a cooling module for each module, each cooling module being configured to cool the inner space of the associated module

20. The modular data centre unit according to any preceding clause, wherein the cooling module comprises a sealed air plenum.

21. The modular data centre unit according to any of clauses 3 to 20, wherein at least one face of the frame structure comprises at least one detachable panel, the detachable panel allowing access to and the attachment of adjacent modules.

22. The modular data centre unit according to clause 21, wherein at least two faces of the frame structure comprise detachable panels.

23. The modular data centre unit according to any preceding clause, wherein at least one face of the at least one module comprises at least one detachable door, the detachable door allowing access to the at least one module.

24. The modular data centre unit according to clause 23, wherein at least one face of the at least one module comprises at least two detachable doors.

25. The modular data centre unit according to clause 23 or clause 24, wherein at least two faces of the at least one module comprise detachable doors.

26. The modular data centre unit according to any of clauses 21 to 25, wherein the material of the detachable panels is steel, and/or precast concrete, and/or, re-enforced insulation, and/or wire, and/or timber boarding, and/or timber boarding within a steel enclosure.

27. The modular data centre unit according to any preceding clause, wherein the module comprises hermetically-sealed internal glass doors.

28. The modular data centre unit according to any preceding clause, further comprising a fire system, and/or a security system, and/or maglocks, and/or leak detection, and/or internally lined rockwool, and/or building management system, and/or DCIM, and/or infrastructure, and/or CCTV, and/or fire suppression, and/or wireways, and/or electrical switchgear.

29. The modular data centre unit according to any preceding clause, configured to be deployed as a plurality of separate modules configured to be assembled onsite.

30. The modular data centre unit according to any preceding clause, wherein each module is fully occupied by computing equipment without any allocated space for a human to walk through.

31. The modular data centre unit according to any preceding clause, configured to be fully occupied by computing equipment without any allocated space for a human to walk through the modular data centre unit.

1. A modular data centre unit comprising:
at least one module, each module defining an interior space, intended to house computing equipment mounted on racks or cabinets; and
at least one cooling module configured to cool the inner space of the at least one module,
wherein the at least one module is configured to enable horizontal and/or vertical arrangement in which a plurality of modules are arranged adjacent to one another.

2. The modular data centre unit according to claim 1, wherein the at least one module is configured to enable horizontal and/or vertical arrangement in which a plurality of modules are arranged contiguous with one another.

3. The modular data centre unit according to claim 1, further comprising a frame structure configured to support at least the at least one module, wherein the frame structure comprises a front face, a back face, two side faces, a bottom face, and a top face.

4. The modular data centre unit according to claim 3, wherein the frame structure is a dual structure frame and comprises variable vibration mounts and seismic stabilizers.

5. The modular data centre unit according to claim 1, wherein the at least one module comprises connection means to connect the computing equipment, and
wherein the frame structure comprises connection means to connect adjacent frame structure and modules.

6. The modular data centre unit according to claim 5, wherein the connection means to connect modules or to connect the computing equipment are holes and electrical trunking to allow the connection of wiring, and wherein the connection means to connect the adjacent frame structure is concealed fixing with an insulated partition.

7. The modular data centre unit according to claim 3, wherein the frame structure is structurally separate from each module, and each module is structurally separate from adjacent modules, and
wherein the frame structure is electrically isolated from the racks within each module.

8. The modular data centre unit according to claim 3, wherein the frame structure is configured to allow the connection of racks within modules in horizontal and vertical planes.

9. The modular data centre unit according to claim 1, wherein the computing equipment is at least one of:
a storage module;
a power module; and
a network module.

10. The modular data centre unit according to claim 1, wherein the at least one cooling module comprises a cooling system configured to be remote or to be connected to any part of the at least one module of the modular data centre unit.

11. The modular data centre unit according to claim 1, further comprising a cooling module for each module, each cooling module being configured to cool the inner space of the associated module.

12. The modular data centre unit according to claim 1, wherein the cooling module comprises a sealed air plenum.

13. The modular data centre unit according to claim 3, wherein at least one face of the frame structure comprises at least one detachable panel, the detachable panel allowing access to and the attachment of adjacent modules.

14. The modular data centre unit according to claim 13, wherein at least two faces of the frame structure comprise detachable panels.

15. The modular data centre unit according to claim 1, wherein at least one face of the at least one module comprises at least one detachable door, the detachable door allowing access to the at least one module.

16. The modular data centre unit according to claim 1, wherein the module comprises hermetically-sealed internal glass doors.

17. The modular data centre unit according to claim 1, further comprising at least one of: a fire system, a security system, maglocks, leak detection, internally lined rockwool, building management system, DCIM, infrastructure, CCTV, fire suppression, wireways, and electrical switchgear.

18. The modular data centre unit according to claim 1, configured to be deployed as a plurality of separate modules configured to be assembled onsite.

19. The modular data centre unit according to claim 1, wherein the at least one module and the frame structure are configured to be deployed as a set of parts and assembled onsite.

20. The modular data centre unit according to claim 1, wherein the modular data centre unit and each module are fully occupied by computing equipment without any allocated space for a human to walk through.
